(19) United States
(12) Patent Application Publication
(10) Pub. No.: US 2010/0211982 A1
(43) Pub. Date: Aug. 19, 2010

(54) A/V PREMISES DECODER, A CONTENT MANAGER, A VIDEO INSERTION SYSTEM INCLUDING BOTH THE DECODER AND MANAGER, AND A METHOD OF INSERTING LOCAL CONTENT INTO A VIDEO STREAM AT A CUSTOMERS PREMISES

(75) Inventors: Wonsuck Lee, Basking Ridge, NJ (US); Minkyu Lee, Ringoes, NJ (US)

Correspondence Address: HITT GAINES, PC;ALCATEL-LUCENT, PO BOX 832570, RICHARDSON, TX, 75083, US

(73) Assignee: Alcatel-Lucent USA, Incorporated, Murray Hill, NJ (US)

(21) Appl. No.: 12/388,475

(22) Filed: Feb. 18, 2009

(51) Int. Cl. H04N 7/173; H03M 1/12

(52) U.S. Cl. 725/93; 348/572

(57) ABSTRACT

A multimedia (audio and video) insertion system, an A/V premises decoder, a content manager and a method of inserting local content into a multimedia stream at a customer's premises. In one embodiment, the A/V premises decoder includes: (1) a signal converter configured to convert a received digital multimedia stream to an analog multimedia stream, and (2) a content inserter configured to insert secondary content in the analog multimedia stream based on control information associated with the secondary content.

### TECHNICAL FIELD

This application is directed, in general, to inserting content into a video stream and, more specifically, to inserting local content into a network digital television signal.

### BACKGROUND

Digital television signals are broadcast according to formats, such as standards (e.g., MPEG-2 and MPEG-4) from the Moving Pictures Expert Group (MPEG) or H.264 from the Telecommunication Standardization Sector of the International Telecommunication Union (ITU-T). Compliance with the applicable standards being used is needed in order for the digital video stream to be correctly decoded at a customer's set-top-box (i.e., a decoder). Additions to broadcasted digital television signals, such as local advertisements, are no exception to these requirements. Therefore, the ad-insertion task or ad-splicing must make the resulting video stream conform to the standard requirements. Visually seamless insertion of the local advertisements, however, into a main video stream within a compressed digital domain can be a challenging task since the exact location of IBP frames are not generally known for compressed video signals. Moreover, the resulting video stream needs to conform to the applicable standard to be decoded without a problem. Thus, transport digital video stream splicing can be a complicated and difficult task.

In order to insert local advertisements, splicing tasks are typically performed at locations which are geographically local to customers. There are typically two ways of doing splicing. First, one can decode the encoded digital video stream and perform splicing in analog domain and re-encode the stream to transport in digital domain. Although widely used, this is not a desirable solution since it involves extra decoding and encoding steps. Nevertheless, the spliced stream can be seamless since the spliced stream is essentially a newly generated stream from an encoder. However, the extra tandem coding process often results in degraded video quality. Second, splicing may be performed in a compressed (encoded) domain at the packet level while ensuring the spliced stream complies with the applicable standard. Splicing at the compressed domain, however, can often result in compliance problems with the applicable standard when decoding the resulting digital video stream at the decoder of the customer. Furthermore, it is even more difficult to make the spliced stream visually seamless.

### SUMMARY

One aspect provides an A/V premises decoder. In one embodiment, the A/V premises decoder includes: (1) a signal converter configured to convert a received digital multimedia stream to an analog multimedia stream and (2) a content inserter configured to insert secondary content in the analog multimedia stream based on control information associated with the secondary content.

In another aspect, a content manager is provided. In one embodiment, the content manager includes: (1) a content reservoir configured to store multiple secondary content, (2) a content controller configured to select at least one of the secondary content and generate control information therefore and (3) a content transceiver configured to deliver the at least one of the secondary content and the associated control information to a remote A/V premises decoder.

In yet another aspect, a multimedia insertion system is provided. In one embodiment, the multimedia insertion system includes: (1) an A/V premises decoder configured to receive a digital multimedia stream and convert the digital multimedia stream to an analog multimedia stream and (2) a content manager configured to deliver secondary content and associated control information to the A/V premises decoder, the A/V premises decoder further configured to insert the secondary content in the analog multimedia stream based on the control information.

In still yet another embodiment, a method of inserting local content into a primary multimedia stream at a customer's premises is provided. In one embodiment, the method includes: (1) selecting content to insert in the primary multimedia stream, (2) transmitting the selected content and control information associated therewith to the customer's premises, (3) receiving the selected content and the control information at the customer's premises and (3) inserting the selected content into the primary multimedia stream at the customer's premises employing the control information, wherein the inserting is performed in an analog domain.

### BRIEF DESCRIPTION

Reference is now made to the following descriptions taken in conjunction with the accompanying drawings, in which:

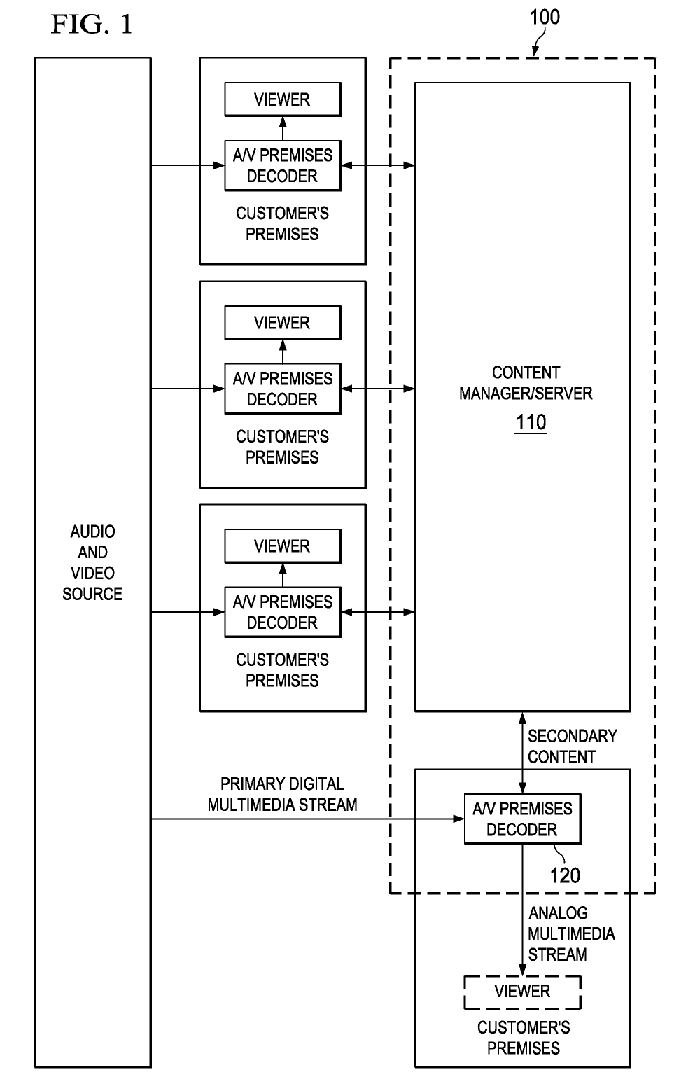

FIG. 1 is a block diagram of an embodiment of an advertising system constructed according to the principles of the present disclosure;

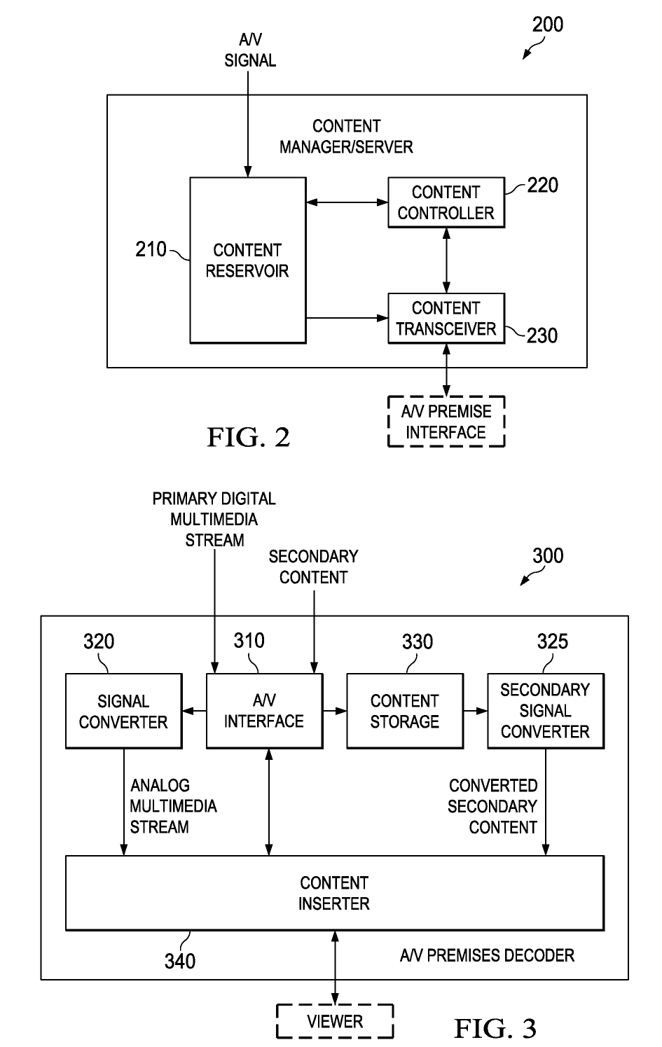

FIG. 2 is a block diagram of an embodiment of a content manager constructed according to the principles of the present disclosure;

FIG. 3 is a block diagram of an embodiment of an A/V premises decoder constructed according to the principles of the present disclosure; and

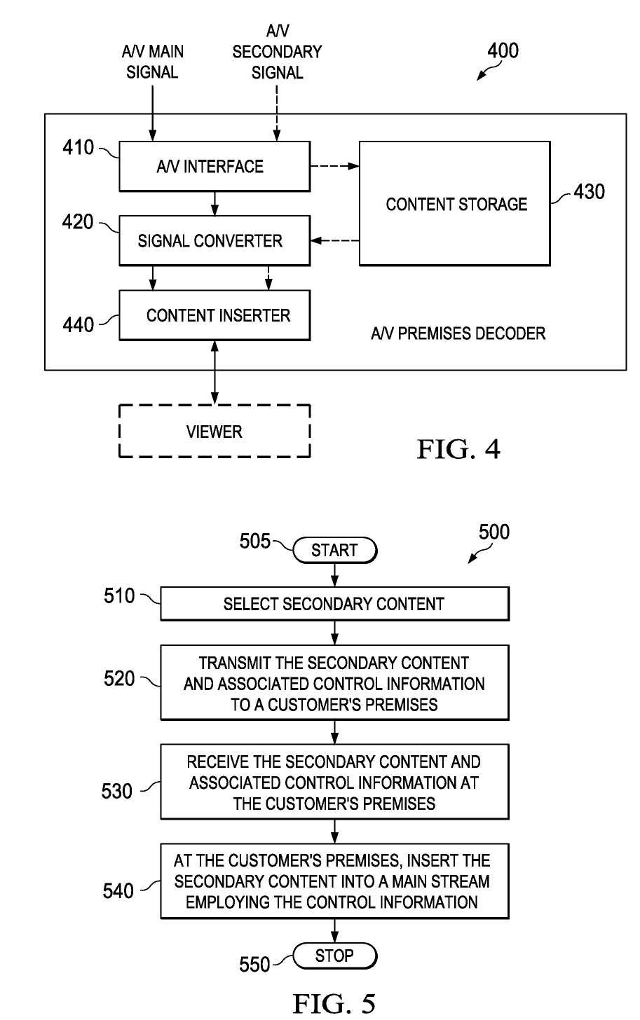

FIG. 4 is a block diagram of another embodiment of an A/V premises decoder constructed according to the principles of the present disclosure; and

FIG. 5 is a flow diagram of an embodiment of a method of inserting analog content into a video stream at a customer's premises carried out according to the principles of the present disclosure.

### DETAILED DESCRIPTION

Disclosed herein is a system and method for inserting content, such as local advertisements, into a multimedia stream at a customer's premises. An A/V premises decoder (which is configured to perform at least some of the functionality of a set-top-box), where all the video layer information is available, is employed to perform the content insertion at the customer's premises. Therefore, the programming deliverers, such as terrestrial (over-the-air), cable, and direct broadcast satellite TV providers, do not have to deal with the complexity of video splicing in the compressed digital domain. Instead, by inserting content at the customer's premises in the analog domain, truly visually seamless splicing can be achieved before delivery to the customer's viewer. The viewer provides video and audio output for the customer. For example, the viewer may be a television or a computer monitor.

A content manager is also disclosed herein that can provide the content to the A/V premises decoder. The content manager can direct the type of advertisements or secondary multimedia content (e.g., in contrast to nation wide broadcasts of primary multimedia content) to deliver to customers and monitor the viewing of the advertisements or the secondary programs. As such, advertisers can have less uncertainty in the displaying of advertisements and have more certainty in knowing service level agreements are satisfied. Greater certainty in displaying advertisements can be achieved due to the content manager/server and an insertion system residing on A/V premises decoders that display the material in pre-defined order agreed on between network service providers and advertisers or the payee of the secondary materials. Additionally, the disclosed architecture allows for highly targeted advertising.

The disclosed apparatuses, system and method do not require a network element for splicing content into a video stream. Additionally, the disclosed apparatuses, system and method do not require extra decoding or re-encoding steps since insertion is performed in the analog domain. As such, the picture on the customer's viewer can be visually seamless.

FIG. 1 is a block diagram of an embodiment of a video insertion system 100 constructed according to the principles of the present invention. The multimedia insertion system 100 is configured to insert content into a multimedia stream in the analog domain at a customer's premises. As such, network splicing and the difficulty of splicing in the digital domain can be avoided. The video insertion system 100 can be used as an advertising system that allows local advertisements to be added to a primary multimedia stream at the customer's premises instead of at the network level. The video insertion system 100 includes a content manager 110 and at least one A/V premises decoder. The A/V premises decoder 120 is denoted to represent the multiple illustrated A/V premises decoders at the various customers' premises. Also illustrated in FIG. 1 is an audio and video source and viewers associated with the different A/V premises decoders located at the various customers' premises.

The audio and video source provides a digital multimedia stream to the A/V premises decoder 120. The audio and video source may be a video server at a central office. The audio and video source may be a conventional A/V provider that delivers digital multimedia streams in a standard manner. In one embodiment, the audio and video source may deliver a digital multimedia stream to the A/V premises decoder 120 according to Internet Protocol over a network structure (i.e., Internet Protocol Television (IPTV)). In other embodiments, the audio and video source may deliver the digital multimedia stream through traditional broadcast, cable or satellite formats. As such, the audio and video source can be a cable company, a satellite company, a television station, etc. The digital video stream, therefore, can be a digital television signal.

Data of the digital multimedia stream is delivered to the viewer located at the customer's premises via the A/V premises decoder 120. The digital video stream may be delivered, for example, to the A/V premises decoder 120 via cable, via satellite, via a computer network or via a combination thereof. The A/V premises decoder 120 decodes the encoded digital video stream according to the applicable standard being employed and converts it to an analog video stream for the viewer. As such, the A/V premises decoder 120 includes at least some functionality that is typically included in a conventional set-top-box. As noted below, the A/v premises decoder 120 also includes added functionality.

The content manager/server 110 is configured to deliver secondary multimedia content and associated control information to the A/V premises decoder 120. The secondary multimedia content may be, for example, local advertisements, promotions or local public service announcements. The content manager 110 is responsible for pushing the secondary content and the control information to the A/V premises decoder 120. The transmission can be conducted at any time of the day, such as, at less busy traffic hours. In one embodiment, the secondary multimedia content may be transmitted as digital content. In another embodiment, the secondary multimedia content may be transmitted as analog content.

The multimedia materials can be stored at a local storage space installed at A/V premises decoder after transmission. The control information may be metadata that the A/V premises decoder 120 will use to direct the insertion of decoded secondary multimedia content into the analog primary multimedia stream. The content manager 110 is configured to receive and store the IP addresses of the A/V premises decoders it manages, viewer profiles, and the capabilities of the A/V premises decoders with respect to bandwidth, storage space, video decoding, etc. As such, the content manager 110 can select the content to deliver to specific A/V premises decoders, the amount of content that can be delivered, the correct protocol needed for delivery, etc.

The A/V premises decoder 120 is further configured to insert the secondary multimedia content in the analog primary multimedia stream based on the control information. In one embodiment, the A/V premises decoder 120 may include a processor and a computer readable storage medium that includes a series of operating instructions that direct the operation of the processor to manage the insertion of the analog content in the analog video stream. The A/V premises decoder 120 is configured to manage the time, duration and the order of insertion for the contents stored on a local storage and prepared by being buffered on a memory of the A/V premises decoder. The control information delivered by the content manager 110 may include the timing information for inserting the secondary content. In addition to the control information, the A/V premises decoder 120 may employ additional data encoded in the primary digital multimedia stream for inserting the secondary content. In one embodiment, the A/V premises decoder 120 may decode tone messages for timing information to insert the analog content. The tone messages may be similar to SCTE-35 tones. SCTE 35 provides a means for inserting digital cue tones into the output of a digital encoder that can be used to trigger switches from a network feed to a different feed such as the stored secondary multimedia content.

For example, the content manager 110 may be an advertising manager and the secondary content may be local advertisements. As such, the content manager 110 delivers appropriate advertising materials to each and every A/V premises decoder, such as A/V premises decoder 120, which it manages. The pushed advertising materials are stored in the storage (e.g., a hard drive) of the A/V premises decoder 120. Different A/V premises decoders may receive different advertising materials. The associated control information, therefore, also transmitted from the content manager 110 to A/V premises decoder 120 may contain information including which order the advertisements are to be inserted based on if a user turns on his/her viewer and if advertising slots are available for the insertion of local advertisements. The order of insertion could depend, for example, on the time of the day, the day or the month. The advertisements and control information can be more customized based on user profiles for targeted advertising. The order of the advertisements may also depend on how much an advertiser may pay the operator if an advertisement assumes higher probability of viewing compared to others. The A/V premises decoder 120, therefore, can be configured to insert local advertisements by switching video source from a network stream to the stored local advertisements. Since all of the video information is available for the stored advertisements, digital domain processing or splicing is not necessary at the A/V premises decoder 120.

FIG. 2 is a block diagram of an embodiment of a content manager 200 constructed according to the principles of the present invention. The content manager may be implemented as a software system running on a server that is remotely located and directly connected to a number of A/V premises decoders to provide secondary multimedia content. The content manager 200 is configured to store secondary multimedia content and manage the distribution of the secondary multimedia content to customers. The secondary multimedia content may be advertisements, particularly local advertisements, which are to be stored, scheduled, and inserted into a network stream delivered to a customer. The content manager 200 may be a dedicated device that is constructed of special purpose hardware employing a series of operating instructions to direct its operation. Other embodiments may employ a device that is solely hardwired or that is solely software enabled using general purpose hardware such as a general purpose computer. In one embodiment, the content manager 200 may be a computer server. The content manager 200 includes a content reservoir 210, a content controller 220 and a content transceiver 230.

The content reservoir 210 is configured to store the secondary multimedia content. The content reservoir 210 may be a conventional memory such as a hard drive. The secondary content may be decoded employing a scheme independent of primary multimedia for deliver and security purpose. The secondary content may be loaded into the content reservoir 210 via conventional means. For example, the secondary content may be loaded to the content reservoir 210 via a computer network, a DVD or video equipment such as a video camera.

The content controller 220 is configured to select the secondary content from the content reservoir 210 for delivery to customers. The content controller 220 also generates control information for the selected secondary contents to deliver therewith. The control information may include a description of the secondary content, the play length, insertion order number, insertion priority value, etc. The insertion priority value may be used with advertisements to ensure service level agreements with advertisers are met. For example, an advertiser may pay extra to ensure that a particular advertisement is inserted first when the customer's viewer is turned on for the first available advertising slot regardless of the channels that he/she is watching. The control information may be metadata generated by the content controller 220 about the secondary content.

The content transceiver 230 is configured to deliver the secondary content and the associated control information to the customer for viewing. As noted in FIG. 1, the content transceiver 230 can deliver the secondary content to an A/V premises decoder at the customer's premises. Additionally, the content transceiver 230 is configured to receive feedback from the customer. The feedback is delivered to the content controller 220 and can be used in future selection of secondary content to be delivered. In one embodiment, the content transceiver 230 is configured to deliver the secondary content and receive feedback via a TCP/IP connection. In other embodiments, the content transceiver 230 may transmit and receive employing a different protocol.

FIG. 3 is a block diagram of an embodiment of an A/V premises decoder 300 constructed according to the principles of the present invention. The A/V premises decoder 300 is located at the premises of a customer and is configured to receive digital multimedia streams that may be viewed by the customer. Typically, the A/V premises decoder 300 is located proximate the viewer of the customer. The A/V premises decoder 300 includes an A/V interface 310, a signal converter 320, a secondary signal converter 325, content storage 330 and a content inserter 340. The A/V premises decoder 300 may also include additional components that are typically included in a set-top-box but are not illustrated or discussed herein.

The A/V interface 310 is configured to provide a data input and data output for the A/V premises decoder 300. As such, the A/V interface 310 is configured to receive a primary digital multimedia stream. The A/V interface 310 may include conventional connections that are included, for example, in a set-top-box. The primary digital multimedia stream may be received via cable, satellite, IPTV, etc. Additionally, the A/V interface 310 is configured to receive the secondary content and the associated control information. As such, the A/V interface 310 may also include, for example, a TCP/IP connector. In some embodiments, a single connector may be used to receive both the primary digital multimedia stream and the secondary content. In other embodiments, the A/V interface 310 may include multiple connectors for receiving the primary digital multimedia stream and the secondary content with the associated control information.

The signal converter 320 is configured to convert the received primary digital multimedia stream to an analog multimedia (e.g., video and audio) stream. The A/V transceiver 320 may also be a conventional device that is included in a set-top-box. The analog multimedia stream can be provided to the viewer for viewing by a customer.

The secondary signal converter 325 is configured to convert secondary content retrieved from the content storage 330 to a converted secondary content (which is analog content) before it is viewed by a customer. The secondary content may be low in bandwidth compared to the primary digital multimedia stream. The secondary signal converter 325 may be configured to operate as the signal converter 320 in terms of decoding function.

The content storage 330 is configured to store the secondary content. The content storage 330 receives the secondary content via the A/V interface 310. The secondary content may be received from a content manager, such as, the content manager 200. The content storage 330 may be a conventional data storage such as a hard drive.

The content inserter 340 is configured to insert the converted secondary content in the analog multimedia stream employing a switching mechanism based on the control information associated with the secondary content. The content inserter 340 may be a dedicated device constructed of special purpose hardware employing a series of operating instructions to direct its operation. Other embodiments may employ a device that is solely hardwired or that is solely software enabled using general purpose hardware such as a general purpose processor. For example, the content inserter 340 may include a processor and a computer readable storage medium that includes a series of operating instructions that direct the operation of the processor to manage the insertion of the converted secondary content in the analog multimedia stream.

The content inserter 340 can direct the insertion of the converted secondary content by switching the video source for the viewer from the signal converter 320 to the secondary signal converter 325. The content inserter 340 can manage the converted secondary content insertion based on the control information. As such, the control information may include the timing information necessary for inserting the analog content. In some embodiments, the content inserter 340 may decode control messages included in the primary digital multimedia stream for timing information. For example, the content inserter 340 may decode a message similar to a SCTE-35 compliant message to determine timing information. As such, the content inserter 340 may also switch between analog streams based on control information associated with the primary digital multimedia stream (which is also converted into the analog multimedia stream via the signal converter 320). Similar control information may be carried in the analog multimedia stream to switch back to the analog multimedia stream at later time.

Employing two different signal converters can allow simultaneous operation to reduce processing time delay from broadcasting to content display. Another embodiment of an A/V premises decoder (e.g., FIG. 4) may use a single signal converter to decode both the primary digital multimedia stream and secondary contents. Employing a single signal converter can require a larger buffer size since more time lag may occur between the actual broadcasting time and the display time compared to the employing two signal converters.

FIG. 4 is a block diagram of another embodiment of an A/V premises decoder 400 constructed according to the principles of the present invention. The A/V premises decoder 400 performs functions as the A/V premises decoder 300 using a different architecture that employs a single signal converter unit 420. The A/V premises decoder 400 is located at the premises of a customer and is configured to receive digital multimedia streams that may be viewed by the customer. The A/V premises decoder 400 includes an A/V interface 410, a signal converter 420, content storage 430 and a content inserter 440. The A/V premises decoder 400 may also include additional components that are typically included in a set-top-box but are not illustrated or discussed herein. Signal converter 420 may contain more buffer space than the signal converter 320 or the secondary signal converter 325 of FIG. 3.

FIG. 5 is a flow diagram of an embodiment of a method 500 of inserting secondary content into a primary multimedia stream at a customer's premises carried out according to the principles of the present invention. The secondary content, for example, may be a local advertisement and the primary multimedia stream may be a broadcasted digital television signal. The method 500 begins in a step 505.

In a step 510, the secondary contents are selected. The secondary content may be selected from the reservoir of a content manager. In one embodiment, the secondary content is selected based on feedback from an A/V premises decoder associated with a viewer of a customer.

After selecting, the secondary content and associated control information are transmitted to a customer's premises in a step 520. The secondary content may be transmitted to an A/V premises decoder located at the customers premises (e.g., a house or an office). The control information may be generated by the content manager for the secondary content. The secondary content and the associated control information may be transmitted via a TCP/IP connection.

The secondary content and the control information are then received at the customer's premises in a step 530. The secondary content and the control information may be received by the A/V premises decoder at the customer's premises. In a step 540 and at the customer's premises, the secondary content is inserted into a primary multimedia stream based on the control information in the analog domain. The A/V premises decoder may perform the insertion. A content inserter of the A/V premises decoder may insert the secondary analog content by switching sources from a decoded A/V signal received by the A/V premises decoder to a memory storing the analog content. The method 500 then ends in a step 550.

The above-described methods or at least portions of the systems and apparatuses may be embodied in or performed by various conventional digital data processors or computers, wherein the computers are programmed or store executable programs of sequences of software instructions to perform one or more of the steps of the methods, e.g., steps of the method of FIG. 5. The software instructions of such programs may be encoded in machine-executable form on conventional digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, e.g., one or more of the steps of the method of FIG. 5. Additionally, an apparatus, such as a type of set-top-box, may be designed to include the necessary circuitry to perform part of the method of FIG. 5.

Those skilled in the art to which this application relates will appreciate that other and further additions, deletions, substitutions and modifications may be made to the described embodiments.

What is claimed is:

1. An A/V premises decoder, comprising:
a signal converter configured to convert a received digital multimedia stream to an analog multimedia stream; and
a content inserter configured to insert secondary content in said analog multimedia stream based on control information associated with said secondary content.

2. The A/V premises decoder as recited in claim 1 wherein said digital multimedia stream is a network television stream.

3. The A/V premises decoder as recited in claim 2 wherein said secondary content is a local advertisement for a geographical area that includes the location of said A/V premises decoder.

4. The A/V premises decoder as recited in claim 1 further comprising a memory configured to store said secondary content.

5. The A/V premises decoder as recited in claim 4 wherein said content inserter is configured to insert said secondary content by selecting said memory as a multimedia source.

6. The A/V premises decoder as recited in claim 5 wherein said content inserter is configured to select said memory as a multimedia source based on said control information.

7. The A/V premises decoder as recited in claim 1 wherein said content inserter selects said secondary content for insertion based on a factor included in said control information, said factor selected from a list consisting of:
time of day,
operating status of viewer associated with said A/V premises decoder,
feedback,
day of week, and
date.

8. A content manager, comprising:
a content reservoir configured to store multiple secondary content;
a content controller configured to select at least one of said secondary content and generate control information therefore; and
a content transceiver configured to deliver said at least one of said secondary content and said associated control information to a remote A/V premises decoder.

9. The content manager as recited in claim 8 wherein said content controller is configured to select said at least one of said secondary content based on said remote A/V premises decoder.

10. The content manager as recited in claim 8 wherein said content manager is couplable to multiple remote A/V premises decoders.

11. The content manager as recited in claim 10 wherein said content controller is configured to select different secondary content to be delivered to different ones of said multiple remote A/V premises decoders.

12. The content manager as recited in claim 10 wherein said content controller is configured to maintain information on each of said multiple remote A/V premises decoders and employ said information to select said at least one of said secondary content.

13. The content manager as recited in claim 12 wherein said information is included in the list consisting of:
IP address,
viewer profiles,
bandwidth capabilities,
memory space, and
video decoding capabilities.

14. A multimedia insertion system, comprising:
an A/V premises decoder configured to receive a digital multimedia stream and convert said digital multimedia stream to an analog multimedia stream; and
a content manager configured to deliver secondary content and associated control information to said A/V premises decoder, said A/V premises decoder further configured to insert said secondary content in said analog multimedia stream based on said control information.

15. The multimedia insertion system as recited in claim 14 wherein said A/V premises decoder includes a memory configured to store said secondary content.

16. The multimedia insertion system as recited in claim 15 wherein said A/V premises decoder further comprises a content inserter configured to insert said secondary content by selecting said memory as a multimedia source.

17. The multimedia insertion system as recited in claim 16 wherein said content inserter is configured to select said memory as a multimedia source based on said control information.

18. The multimedia insertion system as recited in claim 14 wherein said content manager is couplable to multiple remote A/V premises decoders.

19. The multimedia insertion system as recited in claim 18 wherein said content controller is configured to select different secondary content to be delivered to different ones of said multiple remote A/V premises decoders.

20. The multimedia insertion system as recited in claim 18 wherein said content controller is configured to maintain information on each of said multiple remote A/V premises decoders and employ said information for said A/V premises decoder to select said secondary content.

21. A method of inserting local content into a primary multimedia stream at a customer's premises, comprising:
selecting content to insert in said primary multimedia stream;
transmitting said selected content and control information associated therewith to said customer's premises;
receiving said selected content and said control information at said customer's premises; and
inserting said selected content into said primary multimedia stream at said customer's premises employing said control information, wherein said inserting is performed in an analog domain.

22. The method as recited in claim 21 wherein said inserting is performed by switching from a source of said primary multimedia stream to a source of said selected content based on said control information.

23. The method as recited in claim 22 wherein said selected content is secondary content.

24. The method as recited in claim 21 further comprising storing said selected content in a memory after said receiving.

25. The method as recited in claim 21 wherein said primary multimedia stream was received at said customer's premises as a digital television signal.
